(19) United States
(12) Patent Application Publication
(10) Pub. No.: US 2007/0023842 A1
(43) Pub. Date: Feb. 1, 2007

(54) Semiconductor devices having different gate dielectric layers and methods of manufacturing the same

(76) Inventors: Hyung-suk Jung, Suwon-si (KR); Jong-ho Lee, Suwon-si (KR); Ha-jin Lim, Seoul (KR); Yun-seok Kim, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/432,717

(22) Filed: May 12, 2006

Related U.S. Application Data
(63) Continuation-in-part of application No. 10/930,943, filed on Sep. 1, 2004.

(30) Foreign Application Priority Data
Aug. 8, 2005 (KR) 2005-0072331
Nov. 12, 2003 (KR) 2003-0079908

(51) Int. Cl. H01L 29/94; H01L 29/768; H01L 21/8238

(52) U.S. Cl. 257/369; 438/216

(57) ABSTRACT

A first transistor includes a first channel region of a first conductivity type located at a first surface region of a semiconductor substrate, a first gate dielectric which includes a first HfO₂ layer located over the first channel region, and a first gate located over the first gate dielectric. The first gate includes a first polysilicon layer doped with an impurity of the first conductivity type. The second transistor includes a second channel region of a second conductivity type located at a second surface region of the semiconductor substrate, a second gate dielectric which includes a second HfO₂ layer and an Al₂O₃ layer located over the second channel region, and a second gate located over the second gate dielectric. The second gate includes a second polysilicon layer doped with an impurity of the second conductivity type, and the second conductivity type is opposite the first conductivity type.

### CROSS-REFERENCE TO RELATED APPLICATION(S)

This is a continuation-in-part (CIP) of application Ser. No. 10/930,943, filed Sep. 1, 2004, the entirety of which is incorporated herein by reference.

In addition, a claim of priority is made to Korean Patent Application Nos. 10-2005-0072331 and 2003-0079908, filed on Aug. 8, 2005 and Nov. 12, 2003, respectively, in the Korean Intellectual Property Office, the disclosures of which are incorporated herein in their entirety by reference.

### BACKGROUND OF THE INVENTION

1. Field of the Invention

The present invention generally relates to semiconductor devices and to methods of manufacturing the same, and more particularly, the present invention relates to complementary metal-oxide-semiconductor (CMOS) transistors and to methods of manufacturing the same.

2. Description of the Related Art

Conventional transistor devices, such as metal-oxide-semiconductor (MOS) devices, are characterized by a gate dielectric of silicon oxide or silicon oxynitride interposed between a gate electrode and a channel region. The performance of such devices can be improved by increasing the capacitance between the gate electrode and channel region, and one common method by which the capacitance has been increased is to decrease the thickness of the gate dielectric layers. However, degraded electrical characteristics can result from direct tunneling to the channel region in cases where the gate dielectric of silicon oxide or silicon oxynitride is made too thin. The result is increased leakage current and increased power consumption.

Accordingly, methods have been sought to reduce leakage current while achieving a high gate capacitance. One method investigated by the industry is the use of materials having a high dielectric constant (high-k or high-ε) for the gate dielectric layer. Generally, gate capacitance (C) is proportional to permitivity (ε) and inversely proportional to thickness (t) (i.e., C=εA/t, where A is a constant). Thus, an increase in thickness (t) (e.g., to 40 angstroms or more) for reducing leakage current can be offset by high permitivity (ε).

However, the use of high-k dielectrics for gate dielectric layers suffers drawbacks: This is at least partly because high dielectric materials contain a greater number of bulk traps and interface traps than thermally grown silicon oxides. These traps adversely affect the threshold voltage (Vt) characteristics of PMOS and NMOS devices. As a result, various methods of channel engineering, such as ion implantation, have been proposed in an effort to realize a target threshold voltage for devices utilizing a high-k material as a gate dielectric layer. However, such methods also cause problems such as an increase in drain induced barrier lowering (DIBL) and a decrease in a drain-to-source breakdown voltage (BVDS). Furthermore, the n-channel MOSFETs and p-channel MOSFETs of CMOS transistors generally require different gate dielectric threshold voltage characteristics, thus limiting the effective use of channel engineering techniques.

### SUMMARY OF THE INVENTION

According to an aspect of the present invention, a semiconductor device is provided which includes a first transistor and a second transistor. The first transistor includes a first channel region of a first conductivity type located at a first surface region of a semiconductor substrate, a first gate dielectric which includes a first HfO₂ layer located over the first channel region, and a first gate located over the first gate dielectric. The first gate includes a first polysilicon layer doped with an impurity of the first conductivity type. The second transistor includes a second channel region of a second conductivity type located at a second surface region of the semiconductor substrate, a second gate dielectric which includes a second HfO₂ layer and an Al₂O₃ layer located over the second channel region, and a second gate located over the second gate dielectric. The second gate includes a second polysilicon layer doped with an impurity of the second conductivity type, and the second conductivity type is opposite the first conductivity type.

According to another aspect of the present invention, a method of manufacturing a semiconductor device is provided. The method includes forming a first high-k material layer over a first MOS region and a second MOS region of a semiconductor substrate, and annealing the first high-k layer material layer. The first MOS region has a first channel of a first conductivity type, and the second MOS region has a second channel of a second conductivity type which is opposite the first conductivity type. The method further includes forming a second high-k material layer over the annealed first high-k material layer, and annealing the second high-k material layer. The second high-k material layer has a different material composition than the first high-k material layer. The method further includes selectively removing the annealed second high-k material layer in one of the first and the second MOS regions to expose the annealed first high-k material layer in the other of the first and second MOS regions, and forming a conductive layer over the first and second high-k material layers.

### BRIEF DESCRIPTION OF THE DRAWINGS

The above and other aspects and features of the present invention will become readily apparent from the detailed description that follows, with reference to the accompanying drawings, in which:

FIGS. 1A through 1K are cross sectional views illustrating a method of manufacturing a semiconductor device according to an embodiment of the present invention;

FIG. 2 is a graph illustrating a threshold voltage (Vt) distribution in an NMOS transistor and a PMOS transistor manufactured using a gate dielectric layer made of various combinations of high-k materials;

FIG. 3 is a graph showing a C-V curve obtained from an NMOS transistor manufactured with an Al₂O₃ layer as a gate dielectric layer and the C-V curve obtained from an NMOS transistor manufactured with a silicon oxynitride layer;

FIG. 4 is a graph showing a C-V curve obtained from a PMOS transistor manufactured with an Al₂O₃ layer as a gate dielectric layer and a C-V curve obtained from a PMOS transistor manufactured with a silicon oxynitride layer;

FIG. 5 is a graph showing a C-V curve obtained from a PMOS transistor manufactured with an Al₂O₃ layer as a gate dielectric layer and a C-V curve obtained from a PMOS transistor manufactured with a silicon oxynitride layer to illustrate an influence of an impurity type on threshold voltage characteristics;

FIGS. 6A through 6C are graphs showing the thickness of an Al₂O₃ layer after being subjected to a stripper and an etching solution;

FIGS. 7A through 7D are graphs showing the thickness of an Al₂O₃ layer after being subjected to a stripper and an etching solution;

FIGS. 8A and 8B are graphs showing C-V characteristics according to the number of ALD cycles used to form an Al₂O₃ layer on a HfSiO thin film in NMOS and PMOS transistors; and

FIGS. 9A and 9B are graphs showing a C-V curve illustrating MOS capacitance in NMOS and PMOS transistors with and without a metal nitride layer.

### DETAILED DESCRIPTION OF PREFERRED EMBODIMENTS

The present invention will now be described by way of preferred but non-limiting embodiments.

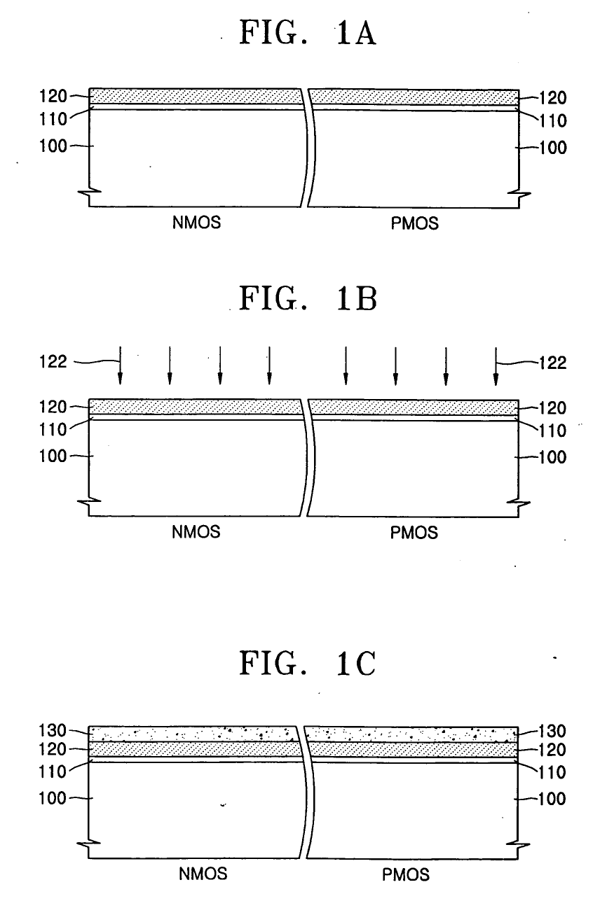

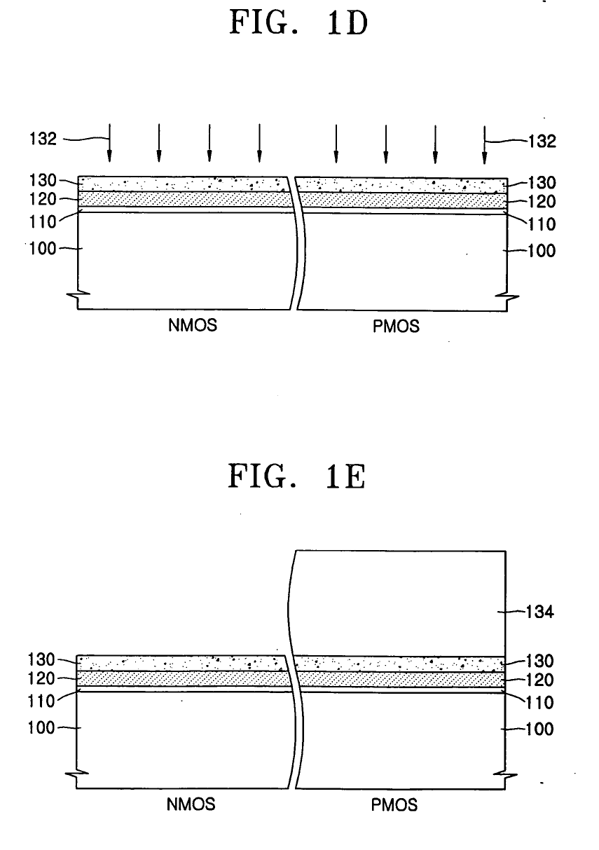

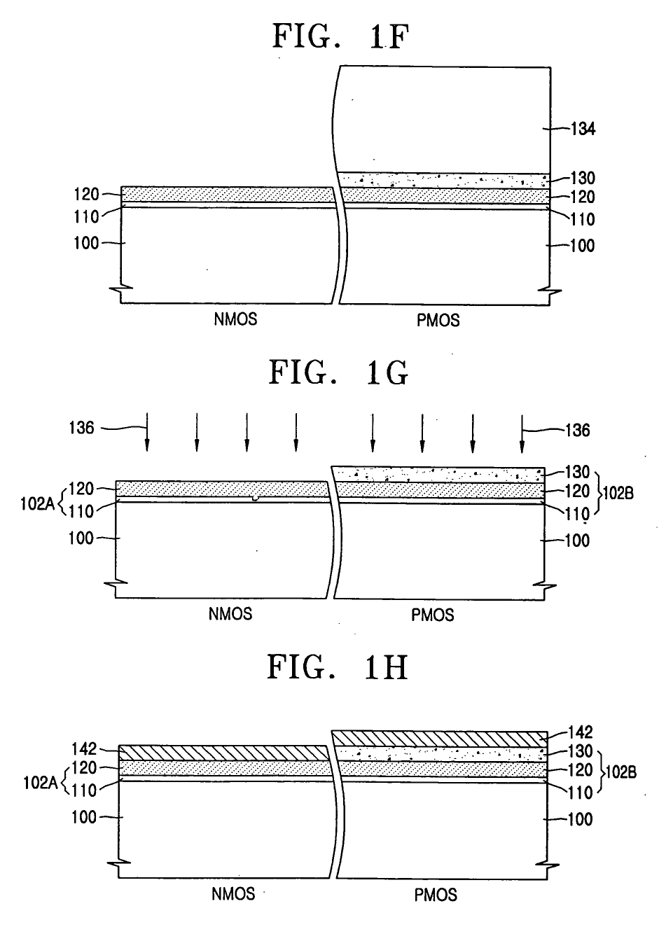

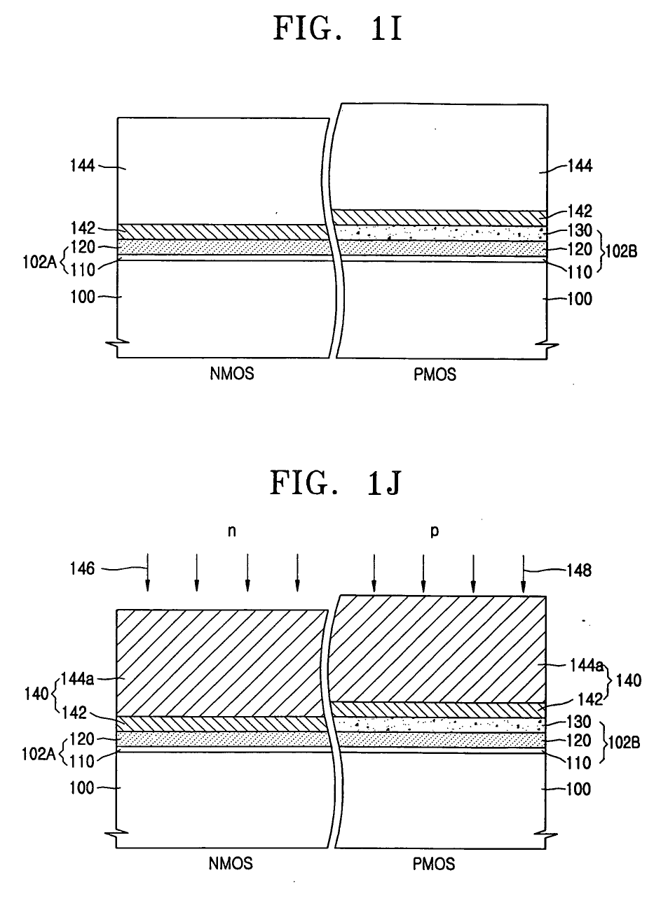

FIGS. 1A through 1K are schematic cross sectional views for use in explaining a method of manufacturing a semiconductor device according to an embodiment of the present invention.

Referring to FIG. 1A, a semiconductor substrate 100 such as a silicon substrate is provided which includes an NMOS region and a PMOS region. An n-channel MOS transistor will be formed on the NMOS region, which is labeled “NMOS” in FIG. 1A, and a p-channel MOS transistor will be formed on the PMOS region, which is labeled “PMOS” in FIG. 1A.

In the example of this embodiment, an interface layer 110 is formed on the NMOS region and the PMOS region with an exemplary thickness in a range from about 0.2 Å to about 15 Å. The interface layer 110 improves the interface characteristics between the semiconductor substrate 100 and a high dielectric constant (high-k, e.g., where k is about 9 or more) material layer which will be later formed on the interface layer 110 in a subsequent process. The interface layer 110 may be formed of a low-k material, e.g., where k is about 8 or less. As examples, the interface layer 100 may be formed of silicon oxide (k equals about 4), silicon oxynitride (k equals about 4-8 according to oxygen content), silicate or combinations of two or more thereof.

In addition, the interface layer 110 may also be treated with ozone gas or ozone water.

A hafnium oxide (HfO₂) layer 120 is formed on the interface layer 110 in both the NMOS region and the PMOS region. The thickness of the HfO₂ layer 120, which may depend on the type of element to be formed, is preferably from about 0.2 Å to about 50 Å, and more preferably from about 5 Å to about 50 Å.

The HfO₂ layer 120 may be formed using a CVD (chemical vapor deposition) process or an ALD (atomic layer deposition) process. The CVD process may be performed with a hafnium source material (e.g., HfCl₄, Hf (OtBu)₄, Hf (NEtMe)₄, Hf(MMP)₄, Hf (NEt₂)₄, Hf (NMe₂)₄) and an oxygen source material (e.g., O₂, O₃, an oxygen radical) at about 400-500° C. and under a pressure of about 1-5 Torr. The ALD process may be performed with a hafnium source material (e.g., HfCl₄, or a metal organic precursor such as, Hf (OtBu)₄, Hf (NEtMe)₄, Hf (MMP)₄, Hf (NEt₂)₄, Hf (NMe₂)₄) and an oxygen source material (e.g., H₂O, H₂O₂, alcohol including an —OH radical, O₃ or O₂ plasma) at about 150-500° C. and under a pressure of about 0.1-5 Torr. The deposition process and a purging process may be repeated until an adequate thickness is obtained. When using the ALD process is utilized to form the HfO₂ layer 120, a low temperature process is possible, good step coverage may be obtained and a layer thickness may be more easily controlled.

Referring to FIG. 1B, the HfO₂ layer 120 is densified by annealing the HfO₂ layer 120 under atmospheric gas 122 (e.g. N₂, NO, N2O, NH₃, O₂ or a mixture thereof. The atmospheric gas 122 may include nitrogen for nitrifying the HfO₂ layer 120. However, the present invention is not limited to the use of such an atmospheric gas. For example, the annealing process may be performed in a vacuum to densify the HfO₂ layer 120.

The annealing process may be performed at about 750-1050° C. The annealing decreases the etch rate of a wet cleaning solution (e.g. a cleaning solution including fluorine). If the annealing is performed at less than 750° C., the etch rate may not be sufficiently reduced, and if the annealing is performed at a very high temperature, crystallization of the HfO₂ layer 120 may occur, resulting in an increase in leakage current. Therefore, the annealing is preferably performed at a temperature ranging from 750 to 1050° C.

Referring to FIG. 1C, as a second high dielectric constant material layer, an aluminum oxide (Al₂O₃) layer 130 is formed on the HfO₂ layer 120. The Al₂O₃ layer 130 may have a thickness of less than about 50 Å. In the present embodiment, the thickness of the Al₂O₃ layer 130 is in the range of about 0.2-50 Å, preferably about 5-50 Å.

The Al₂O₃ 130 may be formed using a CVD (chemical vapor deposition) process or an ALD (atomic layer deposition) process. If an ALD is used, the deposition process may be performed with an aluminum source material (e.g., trimethyl aluminum, AlCl₃, AlH₃N (CH₃)₃, C₆H₁₅AlO, (C₄H₉) ₂AlH, (CH₃) ₂AlCl, (C₂H₅) ₃Al, (C₄H₉) ₃Al) and oxygen source material (e.g., H₂O, H₂O₂, N₂O plasma, O₂ plasma) at about 200-500° C. and under a pressure of about 0.1-5 Torr. The deposition process and a purging process may be repeated until a desired thickness is obtained. If O₃ is used as the oxygen source material, for example, a subsequent annealing step (described next) may be omitted and the thermal budget may thus be minimized.

Referring to FIG. 1D, the Al₂O₃ layer 130 is preferably annealed under an atmospheric gas 132 such as N₂, NO, N₂O, NH₃, O₂ or a combination thereof, or in a vacuum. Preferably, the atmospheric gas 132 includes nitrogen.

The annealing of the Al₂O₃ layer 130 is performed at 400-950° C., preferably 650-850° C. The annealing improves etch resistance to a stripper used during a striping process which is performed to remove a photoresist layer. As a result, consumption of the Al₂O₃ layer 130 may be reduced or prevented.

Referring to FIG. 1E, a photoresist pattern 134 is formed to cover the Al₂O₃ layer 130 in the PMOS region and to expose the Al₂O₃ layer 130 in the NMOS region.

Referring to FIG. 1F, the Al₂O₃ layer 130 on the NMOS region is removed by a cleaning solution using the photoresist pattern 134 as a mask. The cleaning solution may contain fluorine, for example a 200:1 to 500:1 diluted HF solution. Etching of the HfO₂ layer 120 under the Al₂O₃ layer 130 is reduced or prevented since the HfO₂ layer 120 was previously densified through the annealing process discussed previously in connection with FIG. 1B. Therefore, the Al₂O₃ layer 130 is selectively removed as a result of its high etch selection ratio relative to the HfO₂ layer 120, and the HfO₂ layer 120 is exposed in the NMOS region after the Al₂O₃ layer 130 is removed.

Referring to FIG. 1G, the photoresist layer 134 is removed using an ashing process and a striping process. As a result, the HfO₂ layer 120 is exposed in the NMOS region and the Al₂O₃ layer 130 is exposed in the PMOS region. Since the Al₂O₃ layer 130 has an increased etch resistance to the stripper due to the thermal process previously discussed in connection with FIG. 1D, consumption of the Al₂O₃ layer 130 is minimized during stripping of the photoresist pattern 134.

After removing the photoresist pattern 134, the surfaces of the HfO₂ layer 120 and Al₂O₃ layer 130 are annealed in atmospheric gas 136, e.g., N₂, NO, N₂O, NH₃, O₂ or a combination thereof. It is preferable that the atmospheric gas 136 includes nitrogen. The annealing can be performed at about 750-1050° C. If the annealing is performed at less than 750° C., the atmospheric gas 136 is not sufficiently activated to sufficiently densify the high dielectric layers. If the annealing is performed at a very high temperature (e.g., greater than 1050° C.), leakage current can increase.

The annealing densifies the Al₂O₃ layer 130 in the PMOS region to reduce or prevent impurity penetration such as boron (B) penetration which may occur in the PMOS transistor. In addition, the annealing helps avoid abrupt structural changes at the interface between the HfO₂ layer 120 and the Al₂O₃ 130. This is because the annealing can cause the formation of an alloy oxide-layer including Hf and Al between the HfO₂ layer 120 and the Al₂O₃ 130. Also, the annealing may cure surface damage of the HfO₂ layer 120 caused by the stripper or the cleaning solution during wet etching of the Al₂O₃ layer 130 and stripping of the photoresist pattern 134. An Hf-silicate layer (not shown) may be formed by a reaction between the HfO₂ layer 120 and the interface layer 110 depending on the thermal process temperature of the annealing. Therefore, structural change at interface between the HfO₂ layer 120 and the interface layer 110 may be made more gradual.

For purposes of definition herein, it is noted that the phrase “HfO₂ layer” encompasses both a layer containing hafnium and oxygen exclusively, and a layer containing hafnium, oxygen and one or more other elements (such as nitrogen). Likewise, the phrase “Al₂O₃ layer” encompasses both a layer containing aluminum and oxygen exclusively, and a layer containing aluminum, oxygen and one or more other elements (such as nitrogen).

The annealing processes are not limited to those described above, and other annealing processes may be adopted. As examples only, the annealing may include plasma treatment in a nitrogen atmosphere followed by heat treatment in a vacuum, or the annealing may include plasma treatment in a nitrogen atmosphere followed by heat treatment in an oxygen atmosphere.

Referring still to FIG. 1G, as a result of the above-described processes, a first gate dielectric layer 102A comprised of the interface layer 110 and the HfO₂ layer 120 is formed in the NMOS region, and a second gate dielectric layer 120B comprised of the interface layer 110, the HfO₂ layer 120 and the Al₂O₃ layer 130 is formed in the PMOS region. Furthermore, the first gate dielectric layer 102A is thicker than the second gate dielectric layer 102B. That is, gate dielectric layers having different material structures and different thicknesses are formed in the NMOS region and the PMOS region.

Referring to FIG. 1H, a metal nitride layer 142 is formed in the NMOS region and the PMOS region to form gates over the first gate dielectric layer 102A and the second gate dielectric layer 102B. The metal nitride layer 142 may be formed to a thickness of 0.2 to 500 Å according to the desired size of the semiconductor device. In order to manufacture a highly-integrated semiconductor device, the metal nitride layer 142 may be formed to a thickness of about 0.2 Å to 50 Å. The metal nitride layer 142 may, for example, be made of nitrogen and at least one of W, Mo, Ti, Ta, Al, Hf, Zr, Si and Al.

Referring to FIG. 1I, a dielectric polysilicon layer 144 is formed with a predetermined thickness on the metal nitride layer 142 in the NMOS region and the PMOS region by depositing polysilicon, which is a gate material. For example, the thickness of the dielectric polysilicon layer 144 may be about 1000 Å to about 1500 Å.

Referring to FIG. 1J, an n-type impurity 146, e.g., phosphorous (P) or arsenic (A), is doped into the NMOS region, and a p-type impurity 148, e.g., boron (B), is doped into the PMOS region to form a conductive polysilicon layer 144A. As a result, a gate conductive layer 140, comprised of the metal nitride layer 142 and the conductive polysilicon layer 144A, is formed in the NMOS region and the PMOS region.

The electric characteristics of the NMOS transistor and the PMOS transistor can be improved by forming the non-conductive polysilicon layer before forming the conductive polysilicon layer, and then doping with impurities in order to form the gate conductive layer 140. Such a method of forming the gate conductive layer 140 will be described in greater detail later.

Referring to FIG. 1K, the gate conductive layer 140, the first gate dielectric layer 102A and the second gate dielectric layer 102B are patterned to form a gate pattern 152 of an NMOS transistor on the n-type channel region 104 in the NMOS region, and to form a gate pattern 154 of a PMOS transistor on the p-type channel region 106 in the PMOS region. Then, source/drain regions (not shown) are formed in the NMOS region and the PMOS region to complete the formation the NMOS transistor and the PMOS transistor.

In the embodiment described above, the first gate dielectric layer 102A for the NMOS transistor includes the interface layer 110 made of a low-k material and the metal oxide high-k layer, e.g., the HfO₂ layer 120, formed on the interface layer 110. In addition, the second gate dielectric layer 102B for the PMOS transistor includes the interface layer 110 made of a low-k material, and two metal oxide high-k materials, e.g., the HfO₂ layer 120 and the Al₂O₃ layer 130. The threshold voltage of the NMOS transistor can be reduced by using the HfO₂ layer 120 is used as a gate dielectric layer. Also, the threshold voltage of the PMOS transistor can be maintained identical to or nearly identical to that of a transistor having a silicon oxynitride gate dielectric layer by using the Al₂O₃ layer 130 as a gate dielectric layer. Furthermore, penetration of impurities such as boron (B) can be prevented or reduced by forming the second gate dielectric layer 102B at a thickness which is greater than that of the first gate dielectric layer 102A.

Also, in the example of this embodiment, the metal nitride layer 142 is interposed between the conductive polysilicon layer 144A and the first and second gate dielectric layer 102A and 102B. The metal nitride layer 142 reduces or prevents the penetration of impurities such as boron (B) into the PMOS region. Also, the metal nitride layer 142 reduces or prevents gate depletion, which is a drawback of semiconductor devices fabricated according to conventional techniques in which a polysilicon gate electrode layer is formed directly on the gate dielectric layer.

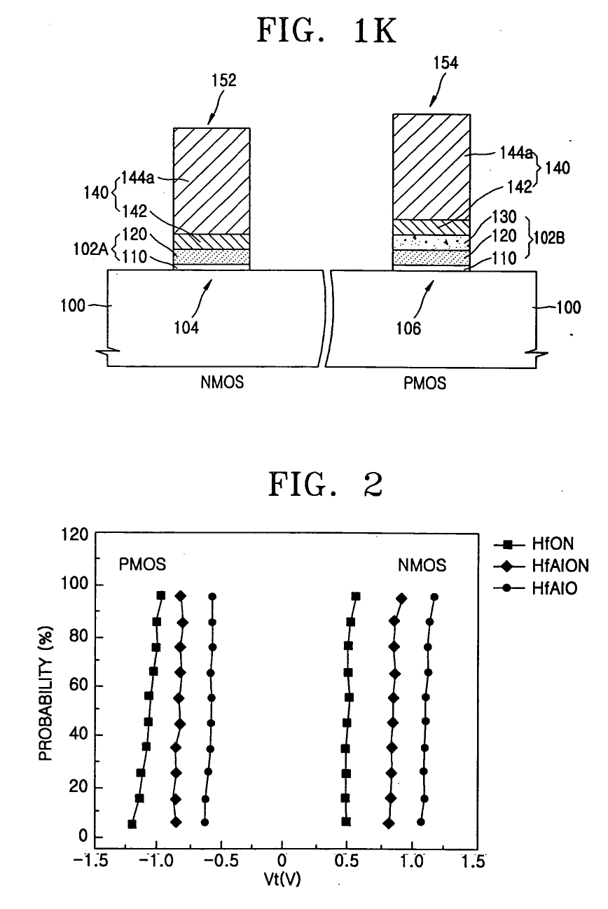

As will be illustrated below with reference to FIGS. 2 through 4, by provisioning the NMOS and PMOS transistors of CMOS devices with different gate dielectric layers, it is possible to overcome drawbacks of the related art in which it is difficult to adequately control respective threshold voltages of the NMOS and PMOS transistors.

FIG. 2 is a graph illustrating the threshold voltage (Vt) distribution in an NMOS transistor and a PMOS transistor manufactured using a gate dielectric layer made of various combinations of high-k materials.

Referring to FIG. 2, when the gate dielectric includes a nitrided HfO₂ layer (HfON), the threshold voltage of the NMOS transistor is about +0.5V, and the threshold voltage of the PMOS transistor is about −1.1V. On the other hand, when the gate dielectric includes a nitrided Hf-Al oxide layer (HfAlON), the threshold voltage of each of the NMOS transistor is about 0.8V and the threshold voltage of the PMOS transistor is about −0.8V. Finally, when the gate dielectric includes Hf-Al oxide (HfAIO) layer, a threshold voltage of the NMOS transistor is about +1.1V and a threshold voltage of the PMOS transistor is about −0.7V.

As demonstrated in FIG. 2, the threshold voltages of the NMOS and PMOS transistors differ according to the material composition of the gate dielectrics. The results illustrated in FIG. 2 indicate that a nitrided HfO₂ gate dielectric layer (HfON) results in the lowest threshold for the NMOS transistor, and that a Hf-Al oxide gate dielectric layer (HfAIO) results in the lowest threshold for the PMOS transistor.

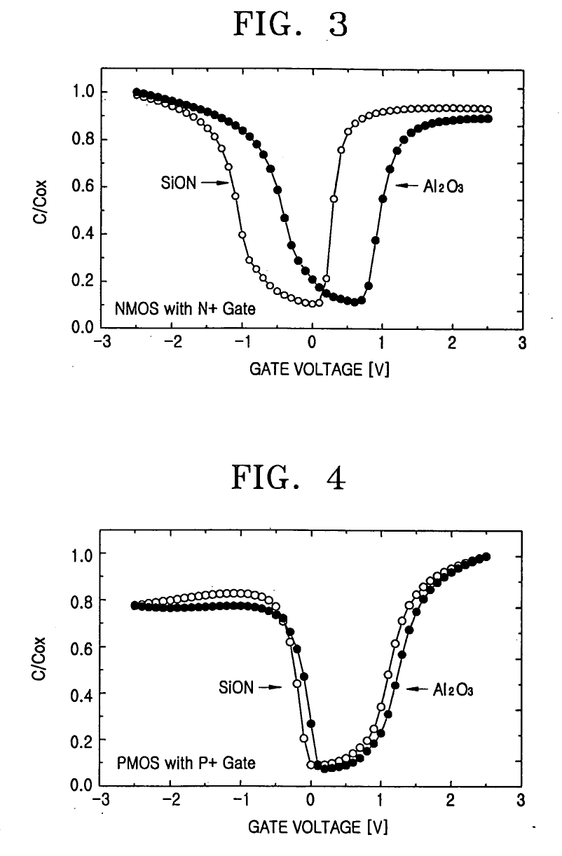

FIG. 3 is a graph illustrating C-V curves respectively obtained from an NMOS transistor containing an Al₂O₃ gate dielectric layer and an NMOS transistor containing a silicon oxynitride (SiON) gate dielectric layer. Both NMOS transistors are otherwise the same, and both include a gate electrode made of an n-type impurity doped polysilicon.

As shown in FIG. 3, the threshold voltage of the NMOS transistor having the Al₂O₃ gate dielectric layer is about 1.0V larger than the threshold voltage of the NMOS transistor having the silicon oxynitride (SiON) gate dielectric layer.

FIG. 4 is a graph illustrating C-V curves respectively obtained from a PMOS transistor-containing an Al₂O₃ gate dielectric layer and a PMOS transistor containing a silicon oxynitride (SiON) gate dielectric layer. Both PMOS transistors are otherwise the same, and both include a gate electrode made of an p-type impurity doped polysilicon.

Referring to FIG. 4, the threshold voltage of the PMOS transistor having the Al₂O₃ gate dielectric layer is about the same as the threshold voltage of the PMOS transistor having the silicon oxynitride (SiON) gate dielectric layer.

From the results of FIGS. 3 and 4, it can be seen that the increase in threshold resulting from the use of an Al₂O₃ dielectric layer is greater for the NMOS transistor than for the PMOS transistor.

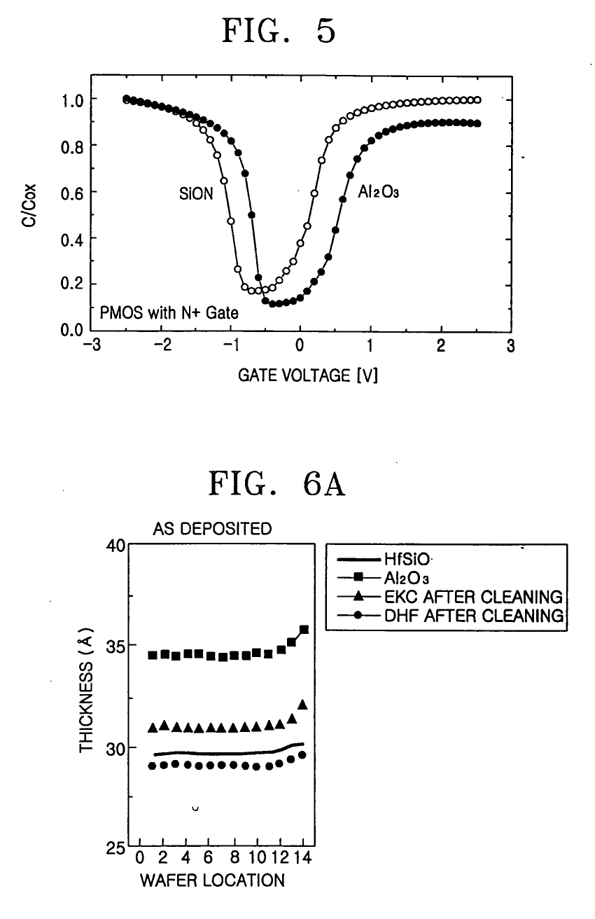

FIG. 5 is a graph showing C-V curves. illustrating the influence of an impurity type in a conductive layer on the threshold voltage characteristics in a semiconductor device according to embodiments of the present invention.

In order to obtain the C-V curve in FIG. 5, a PMOS transistor was manufactured in the same manner as the PMOS transistor used to obtain the results of FIG. 4, except that a gate made of an n-type impurity doped polysilicon was used to obtain the results of FIG. 5.

The C-V curve of FIG. 5 shows that a flat-band voltage is shifted in the positive direction related to the C-V curve obtained from the PMOS transistor with the p-type impurity. This indicates that proper threshold voltage characteristics can be obtained by forming a gate doped with an impurity of a same conductivity type as that of the channel.

Flat-band voltage shift (Vfb) and transconductance (Gm) were measure for each of two different methods of doping an impurity into a polysilicon layer to form a conductive layer for a gate made of polysilicon. In the first method, the doping of the impurity into the polysilicon layer was performed in-situ together with deposition, and in the second method an ion implantation was performed after depositing a polysilicon layer. Here, a SiON layer was used as a gate dielectric layer, phosphorous (P) was used as an impurity (dopant) for forming a gate of the NMOS transistor, and boron (B) was used as an impurity (dopant) for forming a gate of the PMOS transistor. Results of the analysis are shown below in Table 1.

TABLE 1

| Transistor | Gate | Gate Dopant | Vfb shift [V] | Gm [%] |
|---|---|---|---|---|
| NMOS | N+ | P (separate ion implantation) | 0.67 v | 41 |
| PMOS | P+ | B (separate ion implantation) | 0.13 v | 74 |
| NMOS | N+ | P (in-situ) | 0.90 v | 22 |
| PMOS | P+ | B (in-situ) | 0.74 v | 36 |

As shown in Table 1, the Vfb shift varies with the manner in which doping is executed. More particularly, in-situ doping disadvantageously results in a higher Vfb shift than does separate ion implantation. This may be due to the diffusion-of impurity into the gate dielectric layer during deposition of the polysilicon layer, which in turn may cause an increase in Vfb shift of the SiON gate dielectric layer. The transconductance was also superior when executing a separate ion implantation. Accordingly, the preferred choice is to utilize a separate ion implantation process to dope the polysilicon with impurities.

Thus, when using a high-k material as a gate dielectric layer, the amount of impurity diffused from the gate electrode should preferably be minimized in order to reduce the threshold voltage of the MOS transistor. Further, notwithstanding the influence of the impurities, a target threshold voltage can be achieved by using different gate dielectric layers for the NMOS transistor and the PMOS transistor. This is because the Vfb shifts are different in high-k dielectric layers in the NMOS transistor and the PMOS transistor.

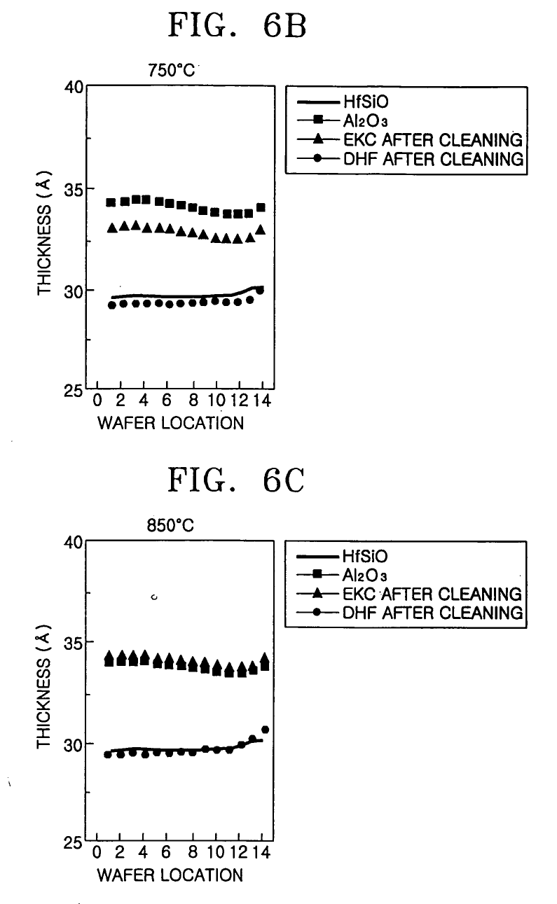

FIGS. 6A through 6C are graphs showing the thickness of an Al₂O₃ layer of a gate dielectric layer in a semiconductor device according to an embodiment of the present invention after being subjected to a stripper and an etching solution.

The sample used to obtain the results illustrated in FIGS. 6A was obtained by forming an HfSiO thin film on a Si wafer, and forming a 0.5 nm thick Al₂O₃ layer on the HfSiO thin film by performing ALD with 6 deposition cycles. The sample used to obtain the results of FIG. 6B was the same as that used to obtain the results of FIG. 6A, except that a thermal process under an N₂ atmospheric gas was performed at 750° C. for 30 seconds. The sample used to obtain the results of FIG. 6C was the same as that used to obtain the results of FIG. 6A, except that a thermal process was performed under an N₂ atmospheric gas at 850° C. for 30 seconds. After obtaining the samples, an amount of the Al₂O₃ layer etched by the etch solution and the stripper were analyzed for each sample. In FIGS. 6A through 6C, black circular dots represent the results of etching the Al₂O₃ layer using 500:1 diluted HF (DHF) for 30 seconds, and black triangular dots denote the results of etching the Al₂O₃ layer using a typical stripper, i.e., EKC manufactured by EKC technology, California, U.S. Black square dots represent a thickness from an upper surface of a wafer to an upper surface of the Al₂O₃ layer and a solid line denotes a thickness from ad upper surface of the wafer to an upper surface of the HfSiO thin film. The horizontal axis in FIGS. 6A through 6C denote various wafer locations where 0 is assigned to a center of the wafer and 14 is assigned to an edge of the wafer.

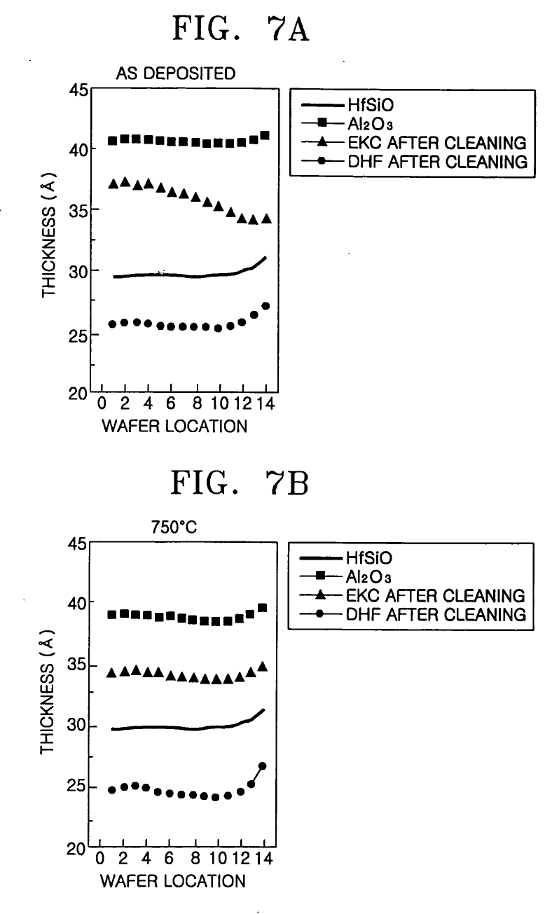

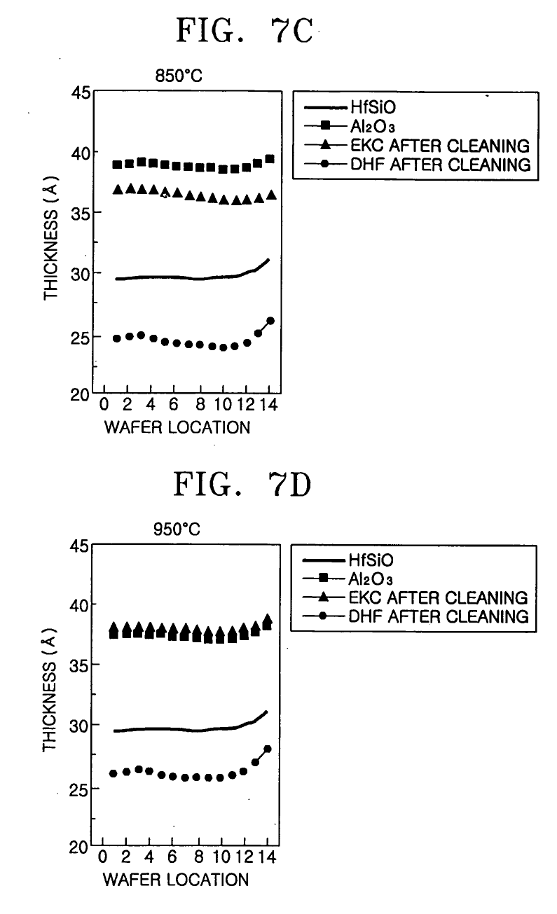

FIGS. 7A through 7D are graphs showing the thickness of an Al₂O₃ layer of a gate dielectric layer in a semiconductor device according to an embodiment of the present invention after being subjected to a stripper and an etching solution.

Samples for FIGS. 7A through 7D were obtained using the same methods as those of the previously described samples relating FIGS. 6A through 6C, except that a 200:1 DHF was used, and except that the Al₂O₃ layer was formed to a thickness of 1 nm by performing the ALD with 12 deposition cycles. Also, thermal processes were performed at 750° C., 850° C., and 950° C. with respect to FIGS. 7B through 7D, respectively.

In the method of manufacturing a semiconductor device according to an embodiment of the present invention, the Al₂O₃ layer is not to be etched away during a stripping process for removing the-photoresist pattern 134 shown in FIG. 1F. However, some of the Al₂O₃ layer can be removed by the stripper, as shown in FIGS. 6A through 6C and 7A through 7D.

FIGS. 6C and 7D show that the Al₂O₃ layer is not etched by the stripper after performing the subsequent thermal process at 850° C. when forming the Al₂O₃ layer using ALD having 6 cycles, and after performing the subsequent thermal process at 950° C. when forming the Al₂O₃ layer using the ALD having 12 cycles. Furthermore, the FIGS. 6C and 7D show that the 850° C. thermal processed Al₂O₃ layer formed using ALD having 6 cycles and the 950° C. thermal processed Al₂O₃ layer formed using ALD having 12 cycles are completely removed when respectively etched in the 500:1 DHF solution and 200:1 DHF solution for 30 seconds. Accordingly, the thermal process should preferably be performed at a proper temperature after forming the Al₂O₃ layer.

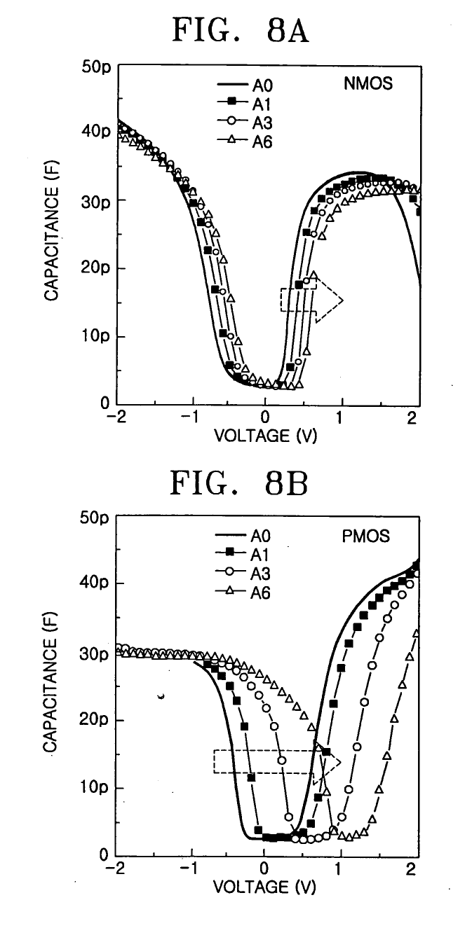

FIGS. 8A and 8B are graphs showing C-V characteristics according to the number of ALD cycles used to form an Al₂O₃ layer on an HfSiO thin film in NMOS and PMOS transistors of a semiconductor device according to an embodiment of the present invention.

The NMOS transistor and the PMOS transistor were formed by forming the HfSiO thin film on a wafer and forming the Al₂O₃ layer on the HfSiO thin film by performing the ALD with 0 cycles (A0), 1 cycle (A1), 3 cycles (A3) and 6 cycles (A6). As shown in FIGS. 8A and 8B, the threshold voltages of the NMOS and PMOS transistor shifted in the positive direction as the number of ALD cycles for the Al₂O₃ layer is increased. However, the threshold voltage is abnormally shifted in the positive direction when more than 3 ALD cycles are used. This may be caused by the penetration of boron (B). That is, the penetration of boron may become significant as the thickness of the Al₂O₃ layer is increased.

Therefore, it is desirable to prevent or minimize the penetration of boron into the Al₂O₃ gate dielectric layer of the PMOS transistor. This can be done, for example, by nitrifying a gate dielectric layer or by interposing a metal layer between a polysilicon gate electrode and the gate dielectric layer.

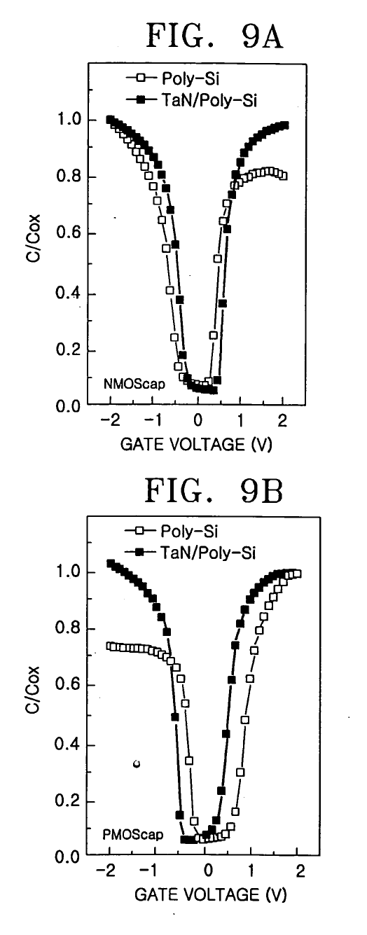

FIG. 9A is a graph of C-V curves indicative of MOS capacitances in an NMOS transistor, and FIG. 9B is a graph of C-V curves indicative of MOS capacitances in a PMOS transistor. Each of FIGS. 9A and 9B illustrate C-V curves with and without the presence of a metal nitride layer between the gate dielectric and the poly-silicon gate electrode. In particular, the C-V curve lines labeled “TaN/Poly-Si” denote MOS capacitances in the case where a metal nitride layer (40 Å) made of TaN is interposed between a poly-silicon gate electrode layer (1500 Å) and a SiO₂ gate dielectric layer (8Å). The C-V curve lines labeled “Poly-Si” denote MOS capacitances without the metal nitride layer.

Referring to FIGS. 9A and 9B, gate depletion is reduced or prevented by interposing the metal nitride layer between the polysilicon layer and the gate dielectric layer. Also, the penetration of boron can be effectively reduced or prevented by the metal nitride layer in the PMOS transistor.

As described above, according to embodiments the present invention, gate dielectrics are formed of selected materials to achieve target threshold voltages of an NMOS transistor and a PMOS transistor. In particular, a gate dielectric of the NMOS transistor includes a HfO₂ layer, while a gate dielectric of the PMOS transistor includes a HfO₂ layer and an Al₂O₃ layer.

Further, a metal nitride layer may be interposed between a polysilicon layer and one or more of the gate dielectrics. The metal nitride layer reduces or prevents dopant penetration in the PMOS region, and reduces or prevents gate depletion in both of the NMOS region and the PMOS region.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor device comprising:
a first transistor comprising a first channel region of a first conductivity type located at a first surface region of a semiconductor substrate, a first gate dielectric which includes a first HfO₂ layer located over the first channel region, and a first gate located over the first gate dielectric, wherein the first gate includes a first polysilicon layer doped with an impurity of the first conductivity type; and
a second transistor comprising a second channel region of a second conductivity type located at a second surface region of the semiconductor substrate, a second gate dielectric which includes a second HfO₂ layer and an Al₂O₃ layer located over the second channel region, and a second gate located over the second gate dielectric, wherein the second gate includes a second polysilicon layer doped with an impurity of the second conductivity type,
wherein the second conductivity type is opposite the first conductivity type.

2. The semiconductor device of claim 1, wherein the first conductivity type is n-type, and the second conductivity type is p-type.

3. The semiconductor device of claim 2, wherein the first gate dielectric further includes a low-k interface layer located between the first HfO₂ layer and the first channel region.

4. The semiconductor device of claim 3, wherein the interface layer includes at least one of silicon oxide, silicon oxynitride or silicate.

5. The semiconductor device of claim 3, wherein a thickness of the interface layer is in a range from about 0.2 Å to about 15 Å.

6. The semiconductor device of claim 3, wherein a thickness of the first HfO₂ layer is in a range from about 0.2 Å to about 50 Å.

7. The semiconductor device of claim 2, wherein the second gate dielectric further includes a low-k interface layer located between the second HfO₂ layer and the first channel region.

8. The semiconductor device of claim 7, wherein the interface layer includes at least one of silicon oxide, silicon oxynitride or silicate.

9. The semiconductor device of claim 7, wherein a thickness of the interface layer is in a range from about 0.2 Å to about 15 Å.

10. The semiconductor device of claim 7, wherein each of the second HfO₂ layer and the Al₂O₃ layer has a thickness in a range-from about 0.2 Å to about 50 Å.

11. The semiconductor device of claim 2, further comprising at least one of a first metal nitride layer located between the first gate dielectric and the first polysilicon layer, and a second metal nitride layer located between the second gate dielectric and the second polysilicon layer.

12. The semiconductor device of claim 11, wherein each of the first metal nitride layer and the second metal nitride layer has a thickness in a range from about 0.2 Å to about 50 Å.

13. The semiconductor device of claim 11, wherein each of the first metal nitride layer and the second metal nitride layer includes nitrogen and at least one metal selected from the group consisting of W, Mo, Ti, Ta, Al, Hf, Zr, Si and Al.

14. The semiconductor device of claim 1, wherein a thickness of the first gate dielectric is different than a thickness of the second gate dielectric.

15. The semiconductor device of claim 2, wherein a thickness of second gate dielectric is greater than a thickness of the first gate dielectric.

16. The semiconductor device of claim 1, wherein at least one of the first HfO₂ layer, the second HfO₂ layer and the Al₂O₃ layer includes nitrogen.

17. A method of manufacturing a semiconductor device, comprising:
forming a first high-k material layer over a first MOS region and a second MOS region of a semiconductor substrate, the first MOS region having a first channel of a first conductivity type, and the second MOS region having a second channel of a second conductivity type which is opposite the first conductivity type;
annealing the first high-k material layer;
forming a second high-k material layer over the annealed first high-k material layer, wherein the second high-k material layer has a different material composition than the first high-k material layer;
annealing the second high-k material layer;
selectively removing the annealed second high-k material layer in one of the first and the second MOS regions to expose the annealed first high-k material layer in the other of the first and second MOS regions; and
forming a conductive layer over the first and second high-k material layers.

18. The method of claim 17, further comprising forming an interface layer of a low-k material on the semiconductor substrate in the first MOS region and the second MOS region before forming the first high-k material layer.

19. The method of claim 18, wherein the interface layer includes at least one of silicon oxide, silicon oxynitride layer, and silicate.

20. The method of claim 18, wherein the thickness of the interface layer is in a range from about 0.2 Å to about 15 Å.

21. The method of claim 17, wherein the first MOS region is an NMOS region and the second MOS region is a PMOS region, wherein the annealed second high-k material layer is removed in the NMOS region to expose the annealed first high-k material layer in the PMOS region, and wherein the first high-k material layer comprises HfO₂.

22. The method of claim 21, wherein the annealing of the first high-k material layer is performed at a temperature from about 750° C. to 1050° C.

23. The method of claim 21, wherein the annealing of the first high-k material layer is performed in an atmospheric gas including at least one compound selected from the group consisting of N₂, NO, N₂O, NH₃ and O₂.

24. The method of claim 21, wherein the first high-k material layer is formed to a thickness of about 0.2 Å to about 50 Å.

25. The method of claim 21, wherein the second high-k material layer includes Al₂O₃.

26. The method of claim 25, wherein the annealing of the second high-k material layer is performed at a temperature of about 400° C. to about 950° C.

27. The method of claim 25, wherein the annealing of the second high-k material layer is performed in a vacuum.

28. The method of claim 25, wherein the annealing of the second high-k material layer is performed in an atmospheric gas including at least one compound selected from the group consisting of N₂, NO, N₂O, NH₃ and O₂.

29. The method of claim 25, wherein the second high-k material layer is formed to a thickness of about 0.2 Å to about 50 Å.

30. The method of claim 25, wherein the selective removal of the second high-k material layer is performed in the first MOS region.

31. The method of claim 25, wherein the selective removal of the second high-k material layer comprises selectively wet etching the second high-k material layer using an etch selectivity between the annealed first high-k material layer and the annealed second high-k material layer.

32. The method of claim 25, wherein the selective removal of the second high-k material layer is performed using a cleaning solution including HF.

33. The method of claim 25, wherein the selective removal of the second high-k material layer comprises selectively removing the second high-k material layer from the NMOS region using a photoresist pattern covering the PMOS region as an etching mask, and removing the photoresist pattern using a stripper after selectively removing the second high-k material layer from the NMOS region.

34. The method of claim 25, wherein the selective removal of the second high-K material layer is performed using a cleaning solution including HF.

35. The method of claim 25, further comprising annealing a resulting structure obtained after selective removal the second high-k material layer and before forming the conductive layer.

36. The method of claim 35, wherein the annealing of the resulting structure is performed under atmospheric gas including a compound selected from the group consisting of N₂, NO, N₂O, NH₃ and O₂.

37. The method of claim 35, wherein the annealing of the resulting structure is performed at a temperature of about 750° C. to about 1050° C.

38. The method of claim 17, wherein the forming of the conductive layer includes:
forming a non-conductive polysilicon layer on the first high-k material layer and the second high-k material layer; and
doping the non-conductive polysilicon layer with an impurity.

39. The method of claim 38, wherein the doping of the non-conductive polysilicon layer comprises doping the non-conductive polysilicon layer with an impurity of the first conductivity type in the first MOS region, and doping the non-conductive polysilicon layer with an impurity of the second conductivity type in the second MOS region.

40. The method of claim 38, wherein the forming of the conductive layer further includes forming a metal nitride layer on the first high-k material layer and the second high-k material layer before forming the non-conductive polysilicon layer, wherein the non-conductive polysilicon layer is formed on the metal nitride layer.

41. The method of claim 40, wherein the thickness of the metal nitride layer is in a range from about 0.2 Å to about 50 Å.

42. The method of claim 40, wherein the metal nitride layer includes nitrogen and at least one metal selected from the group consisting of W, Mo, Ti, Ta, Al, Hf, Zr, Si and Al.
